(19) United States
(12) Patent Application Publication
(10) Pub. No.: US 2004/0207025 A1
(43) Pub. Date: Oct. 21, 2004

(54) Data processor

(75) Inventors: Shoichiro Chiba, Koganei (JP); Koji Okumura, Nagoya (JP); Toshihiro Tanaka, Akiruno (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 10/811,902

(22) Filed: Mar. 30, 2004

(30) Foreign Application Priority Data
Apr. 18, 2003 (JP) 2003-113555

(51) Int. Cl. G11C 11/34

(52) U.S. Cl. 257/390

(57) ABSTRACT

The invention provides a data processor realizing high-speed reading of an on-chip nonvolatile memory and improvement in defect repairing efficiency. For a nonvolatile memory, nonvolatile memory cells each having a split-gate structure including a memory transistor part of an ONO structure and a selection transistor part for selecting the memory transistor part are employed. The gate withstand voltage of the selection transistor part can be lower than that of the memory transistor part, so that it is convenient to increase reading speed. A specific storage region which can be read by a resetting instruction of the data processor is assigned to a storage region in the nonvolatile memory, and repair information and the like is stored in the specific storage region. An internal circuit to which the repair information is transferred replaces a normal storage region instructed by the repair information with a redundant storage region. Thus, a program for an electric fuse and a laser fuse is not required to designate an object to be repaired.

### CROSS-REFERENCE TO RELATED APPLICATION

The present application claims priority from Japanese patent application JP 2003-113555 filed on Apr. 18, 2003, the content of which is hereby incorporated by reference into this application.

### BACKGROUND OF THE INVENTION

The present invention relates to a data processor having an electrically erasable and writable nonvolatile memory and, more particularly, to a technique effective when applied to a microcomputer having an on-chip flash memory.

A technique capable of selecting an operation mode of allowing an internal circuit to control rewriting of a flash memory built in a microcomputer or a mode of allowing an external device such as an EPROM writer to execute the control has been provided (refer to patent document 1).

There are techniques for storing information for repairing a defect in a large-scale integrated circuit or for trimming into an on-chip flash memory and initially loading the information into a corresponding circuit by a resetting process (refer to patent documents 2 and 3).

Nonvolatile memory cells applied to a flash memory or the like include a split-gate type memory cell. A split-gate type memory cell has two transistors; a memory MOS type transistor serving as a memory part and a selection MOS type transistor for selecting the memory part and reading information (non-patent document 1, patent documents 4 and 5 and patent document 6). For example, a split-gate type memory cell of the non-patent document 1 has a source, a drain, a floating gate, and a control gate. Charges are injected to the floating gate by a source-side injection method using generation of hot electrons. Charges accumulated in the floating gate are discharged from a sharp end of the floating gate to the control gate. At this time, it is necessary to apply a high voltage of 12V to the control gate. The control gate functioning as a charge discharge electrode also serves as a gate electrode of a selection MOS type transistor for reading. A gate oxide film of the selection MOS type transistor is a deposited oxide film and also functions as a film for electrically insulating the floating gate and the gate electrode of the selection MOS type transistor.

A stack gate type memory cell includes a source, a drain, and a floating gate and a control gate which are stacked over a channel formation region. Charges are injected to the floating gate by using generation of hot electrons. The charges stored in the floating gate are discharged to the substrate. At this time, it is necessary to apply a high negative voltage of −10V to the control gate. Reading operation is performed by applying a read voltage of 3.3V or the like to the control gate (refer to patent document 7).

[Patent Document 1]

Japanese Unexamined Patent Publication No. Hei 5(1993)-266219

[Patent Document 2]

Japanese Unexamined Patent Publication No. 2000-149588

[Patent Document 3]

Japanese Unexamined Patent Publication No. Hei 7 (1995)-334999

[Patent Document 4]

U.S. Pat. No. 4,659,828

[Patent Document 5]

U.S. Pat. No. 5,408,115

[Patent Document 6]

Japanese Unexamined Patent Publication No. Hei 5(1993)-136422

[Patent Document 7]

Japanese Unexamined Patent Publication No. Hei 11(1999)-232886

[Non-Patent Document 1]

“IEEE, VLSI Technology Symposium, 1994 proceedings”, pp. 71-72

### SUMMARY OF THE INVENTION

From the viewpoint of higher data processing speed, also in nonvolatile memory devices, high speed of the reading operation is important. The split-gate type memory cell has a configuration that the gate electrode of the selection MOS transistor also functions as an erase electrode. In order to assure insulation withstand voltage, the thickness of the gate insulation film has to be the same as that of a high withstand voltage MOS transistor for writing/erasing voltage control. Therefore, Gm (mutual conductance as current supply capability) of the selection MOS transistor is small, and it cannot be said that sufficient read current is assured. In such a state, the split-gate type memory cell is not suitable for high-speed operation with a low voltage. In the case of a stack gate type cell, a thick gate oxide film realizing high withstand voltage is employed for the control gate to which a high voltage is applied in the write/erase operations and it makes Gm in the reading operation small. Consequently, it cannot be said that the stack gate type cell has a structure in which the read current can be obtained sufficiently.

The inventions disclosed in the patent documents 4 and 5 relate to writing and erasing operations and do not mention improvement in performance of the reading operation. The patent document 6 discloses a memory cell similar to that of the present invention. However, the patent document 6 is the invention related to the method of insulating two neighboring gate electrodes from each other and does not disclose reading performance. Therefore, to make the split-gate type memory cell adapted to a data processor of which data processing speed is intended to increase, further devices are necessary.

Some nonvolatile memories employ a hierarchical bit line structure. It is a technique for realizing high-speed reading operation by seemingly reducing the parasitic capacitance on bit lines by memory cells in such a manner that bit lines are arranged in a hierarchy structure of a main bit line and sub bit lines and only a sub bit line to which a memory cell to be selected is connected is selected and connected to the main bit line. However, in the case where application of a high voltage is required for a bit line at the time of writing like the stack gate type memory cell, a high withstand voltage has to be set for a MOS transistor for selectively connecting a sub bit line to the main bit line. Consequently, Gm of a read path is further reduced, and high processing speed realized by the hierarchical bit line structure cannot be sufficiently made function.

An object of the invention is to eliminate a high withstand voltage MOS transistor having a large thickness from a reading path of information stored in a nonvolatile memory.

Another object of the invention is to provide a data processor capable of reading stored information from an on-chip nonvolatile memory at high speed.

The above and other objects and novel features of the invention will become apparent from the description of the specification and the appended drawings.

An outline of representative ones of inventions disclosed in the specification will be briefly described as follows.

1. A data processor according to the invention has a plurality of internal circuits on a semiconductor substrate and includes, as the internal circuits, a nonvolatile memory and a central processing unit. The nonvolatile memory includes a memory array having electrically erasable and writable nonvolatile memory cells constructed by stacking a charge storage insulating film for storing information and a memory gate electrode over a gate insulating film, and a specific storage region which can be read by a reset instruction of the data processor is provided in a part of the memory array. Data read from the specific storage region is repair information by which a normal storage region in a predetermined internal circuit can be replaced with a redundant storage region. Thus, a program for an electric fuse or a laser fuse is not required to designate an object to be repaired, and the efficiency of repairing a defect can be improved.

2. A data processor according to the invention has a plurality of internal circuits on a semiconductor substrate and includes, as the internal circuits, a nonvolatile memory and a central processing unit. The nonvolatile memory includes a memory array having electrically erasable and writable nonvolatile memory cells constructed by stacking a charge storage insulating film for storing information and a memory gate electrode over a gate insulating film, and a specific storage region which can be read by a reset instruction of the data processor is provided in a part of the memory array. Data read from the specific storage region is trimming information by which characteristics of a predetermined internal circuit can be adjusted. Thus, a program for an electric fuse or a laser fuse is not required to adjust circuit characteristics, and the efficiency of adjusting the circuit characteristics can be improved.

3. A data processor according to the invention has a plurality of internal circuits on a semiconductor substrate and includes, as the internal circuits, a nonvolatile memory and a central processing unit. The nonvolatile memory includes a memory array having electrically erasable and writable nonvolatile memory cells constructed by stacking a charge storage insulating film for storing information and a memory gate electrode over a gate insulating film. The data processor has an input terminal of an operation mode signal for selectively designating a first mode of allowing a predetermined internal circuit to control rewriting of information stored in the nonvolatile memory or a second mode of allowing an external device connected to the data processor to control the rewriting. By designating the second mode, before the data processor is mounted on a system, a program, repair information and the like can be efficiently written. By designating the first operation mode, after the data processor is mounted on a system, a program, repair information, and the like can be rewritten on the nonvolatile memory on board.

4. A data processor according to the invention has a plurality of internal circuits on a semiconductor substrate and includes, as the internal circuits, a nonvolatile memory and a central processing unit. The data processor has an input terminal of an operation mode signal for selectively designating a first mode of allowing a first internal circuit to control rewriting of information stored in the nonvolatile memory or a second operation mode of allowing an external device connected to the data processor to control the rewriting. The nonvolatile memory includes a memory array having electrically erasable and writable nonvolatile memory cells constructed by stacking a charge storage insulating film for storing information and a memory gate electrode over a gate insulating film, and a specific storage region which can be read by a reset instruction of the data processor is provided in a part of the memory array. Data read from the specific storage region is repair information by which a normal storage region in a second internal circuit can be replaced with a redundant storage region and trimming information by which characteristics of a third internal circuit can be adjusted.

5. The nonvolatile memory cell has a split-gate structure including a first transistor part (23) used for storing information and a second transistor part (24) for selecting the first transistor part. The first transistor part is of an MONOS type having the charge storage insulating film (31) and a memory gate electrode (34). The second transistor part is of an MOS type.

More specifically, a channel region of the first transistor part and a channel region of the second transistor part are adjacent to each other, and a gate insulating withstand voltage of the second transistor part is lower than that of the first transistor part. A gate insulating film of the second transistor part has the same thickness as that of a gate insulating film of a MOS type transistor as a component of the central processing unit.

With the above configuration, in a data reading operation, when the second transistor part of the nonvolatile memory cell is turned on, stored information is read to a bit line depending on whether current flows or not in accordance with a threshold voltage stage of the first transistor part. Since the gate withstand voltage of the second transistor part is lower than that of the first transistor part, as compared with the case where both of the MOS transistor part for storing information and the MOS transistor part for selection have high withstand voltage, relatively large Gm can be obtained more easily with a low gate voltage relative to the MOS transistor part for selection. The current supply capability of the whole nonvolatile memory cell, that is, Gm can be made relatively large, and increase in the reading speed is realized.

For example, the first transistor part has a source line electrode connected to a source line, the memory gate electrode connected to a memory gate control line, and the charge storage insulating film disposed directly below the memory gate electrode. The second transistor part has a bit line electrode connected to a bit line and a control gate electrode connected to a control gate control line.

In the operation of setting a relatively high threshold voltage in the first transistor part, for example, a high voltage is applied to the memory gate electrode, the second transistor part is turned on, current is passed from the source line to the bit line, and hot electrons generated in a boundary part of the first and second transistor parts are held in the charge storage insulating film. In the operation of setting a relatively low threshold voltage in the first transistor part, for example, a high voltage is applied to the memory gate electrode, the second transistor part is turned on, the ground potential is applied to the bit line electrode and the source line electrode, and hot electrons held in the insulating charge storage layer are discharged to the memory gate electrode. Therefore, the operation of setting a relatively low threshold voltage or a relatively high threshold voltage in the first transistor part can be realized without applying a high voltage to the control gate control line and the bit line. It guarantees that the gate withstand voltage of the second transistor part may be relatively low.

A switch MOS transistor (39) capable of connecting the bit line to a global bit line (GL) may be provided to employ a hierarchical bit line structure (divided bit line structure). By the divided bit line structure, in the reading operation, only part of nonvolatile memory cells are connected to the global bit line, thereby seemingly reducing the parasitic capacitance on the bit line. It contributes to higher speed of the reading operation. Since it is unnecessary to apply a high voltage to the bit line in the erasing/writing operation, the gate oxide film of the switch MOS transistor may be formed thinner than that of the first transistor part. In short, relatively high current supply capability can be easily given to the switch MOS transistor, and higher speed of the reading operation by the divided bit line structure can be guaranteed.

As a more detailed mode, the data processor has a first driver (41) for driving the control gate control line, a second driver (42) for driving the memory gate control line, a third driver (43) for driving the switch MOS transistor to an on state, and a fourth driver (44) for driving the source line. The first and third drivers use a first voltage as an operation power source, and the second and fourth drivers use a voltage higher than the first voltage as an operation power source.

The data processor has a control circuit, at the time of increasing a threshold voltage of the first transistor part, for setting the operation power source of the first driver as a first voltage, setting the operation power source of the fourth driver as a second voltage higher than the first voltage, setting the operation power source of the second driver as a third voltage higher than the second voltage, and enabling hot electrons to be injected from a bit line electrode side into a charge storage region.

At the time of decreasing the threshold voltage of the first transistor part, the control circuit sets the operation power source of the second driver as a fourth voltage higher than the third voltage, and discharges electrons from the charge storage region to the memory gate electrode.

The first transistor part whose threshold voltage is set to be low may be of a depletion type, and the first transistor part whose threshold voltage is set to be high may be of an enhancement type.

At the time of reading information stored in the nonvolatile memory cell, the control circuit may set the operation power source of the first driver as a first voltage and apply the ground potential of the circuit to the memory gate electrode and the source line electrode. The direction of current at the time of the reading operation is the direction from the bit line to the source line.

At the time of reading information stored in the nonvolatile memory cell, the control circuit may set the operation power source of the first driver as a first voltage and apply the ground potential of the circuit to the memory gate electrode and the bit line electrode. The direction of current at the time of the reading operation is, opposite to the above, the direction from the source line to the bit line.

### BRIEF DESCRIPTION OF THE DRAWINGS

FIG. 1 is a block diagram of a microcomputer as an embodiment of the invention.

FIG. 2 is a diagram illustrating a microcomputer placing attention on writing of a flash memory by a general PROM writer.

FIG. 3 is a diagram illustrating a microcomputer placing attention on rewriting of a flash memory by a CPU control.

FIG. 4 is a schematic vertical section showing an example of a nonvolatile memory cell of a split-gate structure employed for a flash memory.

FIG. 5 is a diagram representatively illustrating characteristics of the nonvolatile memory cell of FIG. 4.

FIG. 6 is a diagram illustrating threshold voltage states in the case of a depletion type and an enhancement type of the erase/write state of the nonvolatile memory cell.

FIG. 7 is a diagram illustrating threshold voltage states in the case of an enhancement type of the erase/write state of the nonvolatile memory cell.

FIG. 8 is a diagram showing a write operation of the nonvolatile memory cell of FIG. 5.

FIG. 9 is a diagram illustrating another vertical sectional structure of the split-gate nonvolatile memory cell.

FIG. 10 is a block diagram showing a general configuration of a flash memory.

FIG. 11 is a block diagram showing a circuit configuration for redundant repair in the flash memory.

FIG. 12 is a circuit diagram showing an example of a power source circuit.

### DESCRIPTION OF PREFERRED EMBODIMENTS OF THE INVENTION

Microcomputer

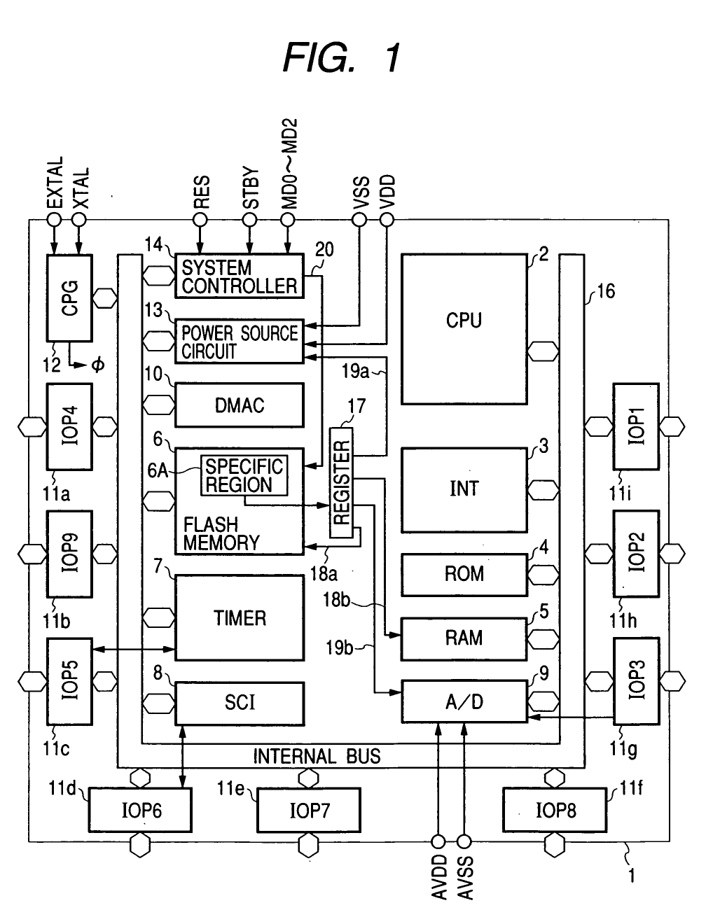

FIG. 1 shows a microcomputer as an embodiment of the invention. A microcomputer 1 shown in the diagram is formed on a semiconductor substrate (semiconductor chip) made of single crystal silicon or the like by, for example, a complementary MOS (CMOS) integrated circuit manufacturing technique.

The microcomputer 1 has functional blocks and modules of a central processing unit (CPU) 2 for controlling the whole, an interrupt controller (INT) 3, a ROM 4 as a nonvolatile memory for storing, mainly, a processing program such as the OS (Operating System) of the CPU 2, a RAM 5 mainly as a work area of the CPU 2 and as a memory for temporarily storing data, a flash memory 6 as a nonvolatile memory for electrically erasably and writably storing a processing program of the CPU 2, repair information, and the like, a timer 7, a serial communication interface (SCI) 8, an analog/digital converter (A/D) 9, a direct memory access controller (DMAC) 10, input/output ports (I/O ports) 11a to 11i, a clock oscillator (CPG) 12, a power source circuit 13, and a system controller 14.

The microcomputer 1 has, as external power source terminals, power source terminals of a ground level (VSS), a power source voltage level (VDD), an analog ground level (AVSS), and an analog power source voltage level (AVDD) and, as other dedicated control terminals, a reset terminal (RES), a standby terminal (STBY), mode control terminals (MD0, MD1, and MD2), and clock input terminals (EXTAL, XTAL).

The microcomputer 1 operates synchronously with a reference clock signal (system clock) φ generated on the basis of an external clock input to a quarts oscillator connected to the terminals EXTAL and XTAL of the CPG 12 or the terminal EXTAL. One cycle of the reference clock signal φ is called a state.

The functional blocks of the microcomputer 1 are connected to each other via an internal bus 16. The microcomputer 1 has therein a not-shown bus controller for controlling the bus. The internal bus 16 includes not only an address bus (ABUS) and a data bus (DBUS) but also a control bus for transmitting bus commands obtained by encoding a read signal, a write signal, and a bus size signal.

The functional blocks and modules are read/written by the CPU 2 via the internal bus 16. The data bus width of the internal bus 16 is 32 bits. The reading/writing operation of the ROM 4 and RAM 5 can be performed in one state.

Control registers of the timer 7, SCI 8, A/D converter 9, input/output ports (IOP) 11a to 11i, power source circuit 13, and system controller 14 are generically called internal I/O registers. The input/output ports 11a to 11i also serve as input/output terminals of the address bus, data sub, control bus, timer 7, SCI 8, and A/D converter 9.

The CPU 2 has a command control part and an execution part. The command control part controls a command fetch and decodes a fetched command. The execution part executes the command by performing an operand access, an arithmetic and logic process, and the like in accordance with a result of the decoding.

The interrupt controller 3 receives interrupt signals from the timer 6, SCI 8, and A/D converter 9 and interrupt signals supplied from the outside of the microcomputer 1, performs a priority control and a mask control on the signals, and requests interruption to the CPU 2. The CPU 2 which receives the interrupt request completes a command being executed and branches to a process according to the interrupt request. The CPU 2 executes, for example, a return command at the end of the process according to the interrupt request, returns to the process interrupted by the branch, and restarts the interrupted process.

The power source circuit 13 decreases, for example, the power of 3.3V (VDD=3.3V and VSS=0V) supplied from the external terminal and supplies an internal power of 1.5V (vdd=1.5V and vss=0V) into the chip. Further, the power source circuit 13 also generates a substrate bias voltage and the like as a substrate power for applying a substrate bias.

When the reset terminal RES changes to the low level or an operation power is supplied to the power source terminal VDD, the modules such as the CPU 2 in the microcomputer 1 are reset. After that, when the reset terminal RES changes from the low level to the high level or after lapse of predetermined time, the reset is canceled. When the reset is canceled, the CPU 2 reads a command from a predetermined start address and starts execution of the command.

When the reset signal RES is supplied to the data processor 1, the on-chip circuit modules such as the CPU 2 are reset. When the reset state by the reset signal RES is canceled, the CPU 2 fetches a command from the start address of a predetermined control program and starts executing the program.

Information in the flash memory 6 can be rewritten by electric erasure and writing. A memory cell in the flash memory 6 can be constructed by a single transistor in a manner similar to an EPROM. The flash memory 6 has a function of electrically erasing all of the memory cells or a block of memory cells (memory block) in a lump. The flash memory 6 has a plurality of memory blocks each as a unit which can be erased in a lump. The storage capacity of a small memory block is set to be smaller than that of the RAM 5. Therefore, the RAM 5 can receive data transferred from a small memory block and temporarily hold the information. In such a manner, the RAM 5 can be used as a work area for rewriting or a data buffer region.

The information stored in the flash memory 6 can be rewritten on the basis of a control of the CPU 2 in a state where the microcomputer 1 is mounted on a system and also can be rewritten under the control of an external writing apparatus such as a general PROM writer. The mode terminals MD0 to MD2 are used as input terminals of an operation mode signal for selectively designating a first operation mode for allowing the CPU 2 to control rewriting of the flash memory 6 or a second operation mode for allowing the external writing apparatus to control rewriting of the flash memory 6.

The flash memory 6 has, in a part of the memory array, a specific storage region 6A which can be read by a reset instruction to the microcomputer 1. As a part of the resetting process of the microcomputer 1, an operation of reading the specific memory region 6A by a control signal 20 output from the system controller 14 is performed. The specific memory region 6A is used as a region for storing repair information capable of replacing a normal storage region in a predetermined internal circuit such as the flash memory 6 or the RAM 5 with a redundant storage region or trimming information capable of adjusting characteristics of a predetermined internal circuit such as the power source circuit 13 or the A/D converter 9. The stored information read from the specific storage region 6A is loaded into a register 17, loaded repair information 18a and 18b is transferred to the flash memory 6 and the RAM 5, and loaded trimming information 19a and 19b is transferred to the power source circuit 13 and the A/D converter 9.

Writing of Information by General PROM Writer

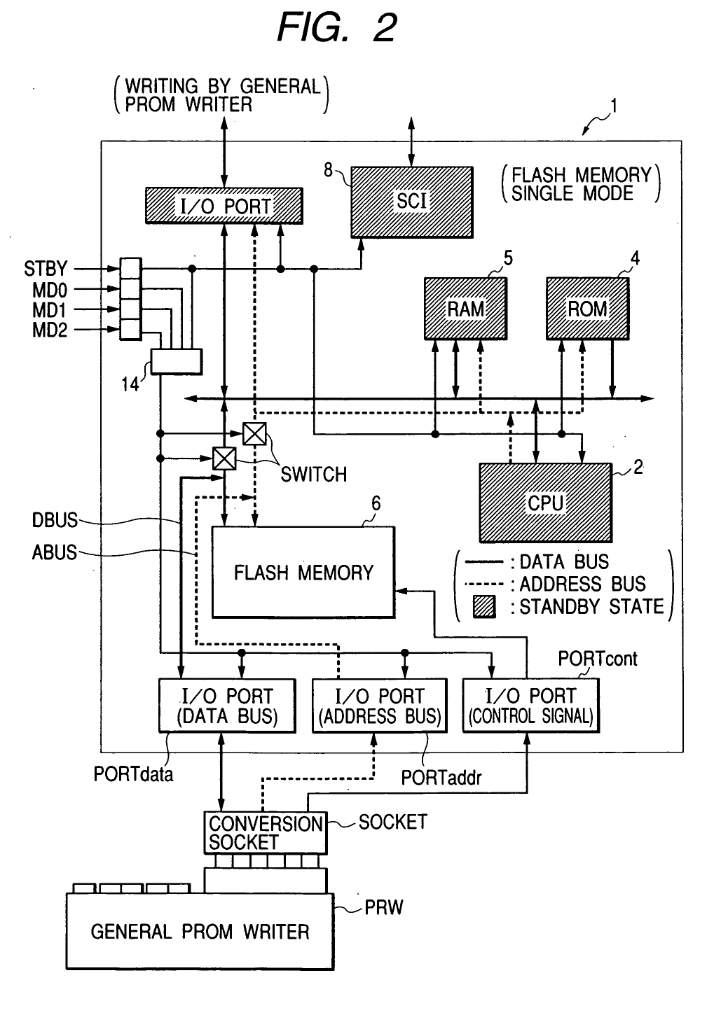

FIG. 2 is a block diagram placing attention to writing of the flash memory 6 by a general PROM writer. The mode terminals MD0 to MD2 are connected to the system controller 14. The system controller 14 decodes a mode signal supplied from the mode terminals MD0 to MD2 and determines which one of the first and second operation modes and other operation modes is instructed. When the second operation mode is instructed, the system controller 14 designates an I/O port as an interface with the general PROM writer PRW and controls the flash memory 6 so as to be directly accessed by the external general PROM writer PRW. Specifically, an I/O port PORTdata for inputting/outputting data from/to the flash memory 6, an I/O port PORTaddr for supplying an address signal to the flash memory 6, and an I/O port PORTcont for supplying various control signals to the flash memory 6 are designated. Further, substantial operations of on-chip functional modules such as the CPU 2, RAM 5, and ROM 4 which are not directly related to the rewrite control by the general PROM writer PRW are suppressed. For example, as shown in FIG. 2, the connection via the bus between the on-chip functional modules such as the CPU 2 and the flash memory 6 is disconnected via switches SWITCH disposed for the data bus DBUS and the address bus ABUS. The switch SWITCH can be grasped as a bus buffer disposed for a circuit for outputting data from the on-chip functional module such as the CPU 2 to the data bus DBUS or a circuit for outputting an address to the address bus ABUS or a tri-state (3-state) gate such as a transfer gate. Such a tri-state gate is controlled to enter an off state (high impedance state) in response to the second operation mode. In FIG. 2, the on-chip functional modules such as the CPU 2, RAM 5, and ROM 4 which are not directly connected to the rewrite control by the general PROM writer PRW are set to a low power consumption mode by a low-level standby signal supplied from the standby terminal STBY. Alternately, by setting the on-chip functional modules into the low power consumption mode in response to designation of the second operation mode by the mode signals MD0 to MD2 in place of the high impedance control of the tri-state gate, the substantial operations of the on-chip functional modules such as the CPU 2, RAM 5, and ROM 4 which are not directly connected to the rewrite control of the general PROM writer PRW may be stopped.

The I/O ports PORTdata, PORTaddr, and PORTcont of the microcomputer 1 which is set in the second operation mode are connected to the general PROM write PRW via a conversion socket SOCKET. The conversion socket SOCKET has terminal arrangement of the I/O ports PORTdata, PORTaddr, and PORTcont and also terminal arrangement of a standard memory. The same function terminals are connected to each other on the inside.

A relatively large amount of information can be efficiently written by the general PROM writer PRW by applying the PROM writer PRW to initially write data or a program before the microcomputer 1 is mounted on a board, that is, a system.

Write Control Program by CPU Control

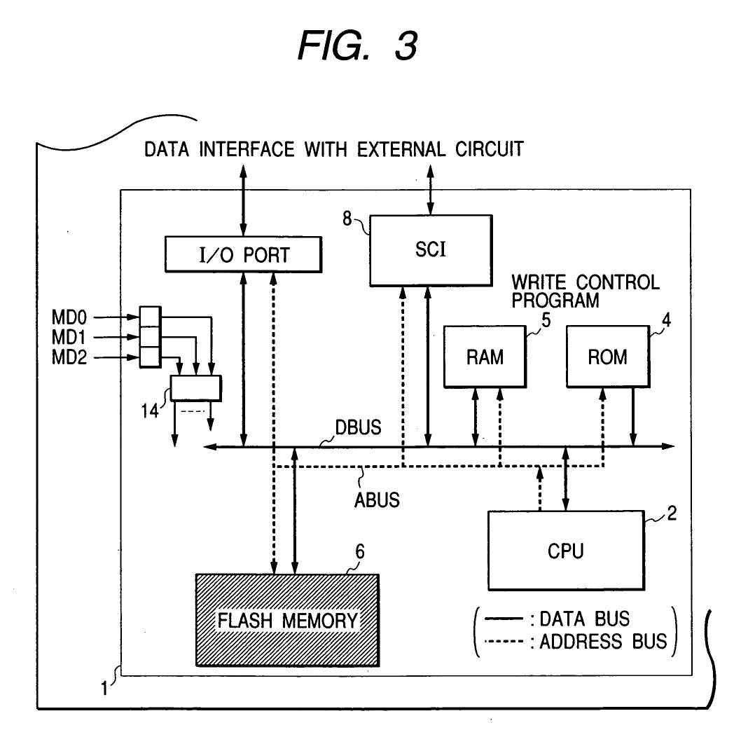

FIG. 3 is a block diagram paying attention to rewriting of the flash memory 6 by CPU control. A rewrite control program to be executed by the CPU 2 is preliminarily written in the flash memory 6 by the general PROM writer PRW or is held in the ROM 4. The microcomputer 1 is mounted on a predetermined system, which is a so-called on-board state. The I/O ports 11a to 11i and the SCI 8 are connected to the bus and external circuits on the system. In such a state, when the first operation mode is instructed via the mode terminals MD0 to MD2 and the system controller 14 recognizes it, the CPU 2 rewrites, or erases and writes data in the flash memory 6 in accordance with a write control program already written in the flash memory 6 or a rewrite control program held in the ROM 4.

It is now assumed that the rewrite control program and a transfer control program are written in advance in a predetermined storage region in the flash memory 6. When the first operation mode is instructed, the CPU 2 executes the transfer control program and transfers the rewrite control program to the RAM 5. After completion of the transfer, the process of the CPU 2 is branched to execution of the rewrite control program on the RAM 5 to perform erasing and writing (including verifying) operation on the flash memory 6. When the rewrite control program is held on the ROM 4, the transfer control program is unnecessary. When the first operation mode is instructed, the CPU 2 sequentially executes the rewrite control program held in the ROM 4 to perform erasing and writing on the flash memory 6.

The writing under control of the CPU is applied to the case of tuning data while operating the system on which the microcomputer 1 is mounted and the case where a change in data or a program becomes necessary in a state where the microcomputer 1 is mounted on the system (on-board state) as a countermeasure against a bug in a program, a change in the program accompanying version-up of the system, or the like. In such a manner, the flash memory 6 can be rewritten without detaching the microcomputer 1 from the system.

Flash Memory

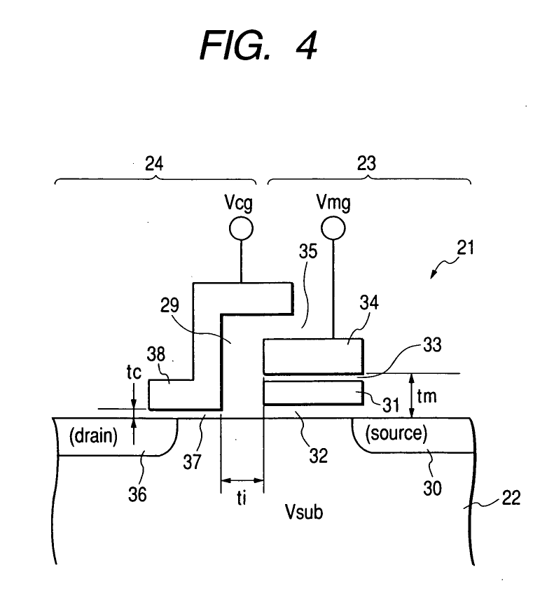

FIG. 4 shows an example of a nonvolatile memory cell (hereinbelow, also simply called a memory cell) employed for the flash memory 6. A nonvolatile memory cell 21 has, in a p-type well region 22 formed in a silicon substrate, a first MOS-type transistor part 23 used for storing information and a second MOS-type transistor part (selection MOS transistor part) 24 for selecting the first transistor part 23. The first transistor part 23 has an n-type diffusion layer (n-type impurity region) 30 as a source line electrode connected to a source line, a charge storage region (for example, silicon nitride film) 31 as an insulating charge storage layer, insulating films (for example, silicon oxide films) 32 and 33 disposed on the surface and the back side of the charge storage region 31, a memory gate electrode (for example, n-type polysilicon layer) 34 for applying a high voltage at the time of writing and erasing, and an oxide film (such as a silicon oxide film) 35 for protecting the memory gate electrode. The insulating film 32 has a thickness of 5 nm, the charge storage region 31 has a thickness of 10 nm (conversion in the silicon oxide film), and the oxide film 33 has a thickness of 3 nm. The second transistor part 24 has an n-type diffusion layer (n-type impurity region) 36 serving as a bit line electrode connected to a bit line, a gate insulating film (for example, silicon oxide film) 37, a control gate electrode (for example, an n-type polysilicon layer) 38, and an insulating film (for example, a silicon oxide film) 29 for insulating the control gate electrode 38 and the memory gate electrode 34. The gate oxide film of the selection MOS transistor part 24 has a thickness which is the same as that of the gate oxide film of a MOS transistor as a component of a logic part typified by the CPU 2.

When the total thickness of the charge storage region 31 in the first transistor part 23 and the insulating films 32 and 33 disposed on the surface and the back side of the charge storage region 31 (which will be called memory gate insulating films 31, 32, and 33) is tm, the thickness of the gate insulating film 37 of the control gate electrode 38 is tc, and the thickness of the insulating film provided between the control gate electrode 38 and the charge storage region 31 is ti, the relation of tc<tm≦ti is satisfied. Due to the dimensional variations in the gate insulating film 37 and the memory gate insulating films 31, 32, and 33, the insulation withstand voltage of the second transistor part 24 is lower than that of the first transistor part 23.

The word “drain” written in the part of the diffusion layer 36 means that the diffusion layer 36 functions as a drain electrode of the transistor in a data reading operation, and the word “source” written in the part of the diffusion layer 30 means that the diffusion layer 30 functions as a source electrode of the transistor in a data reading operation. In an erasing/writing operation, the functions of the drain electrode and the source electrode may be interchanged.

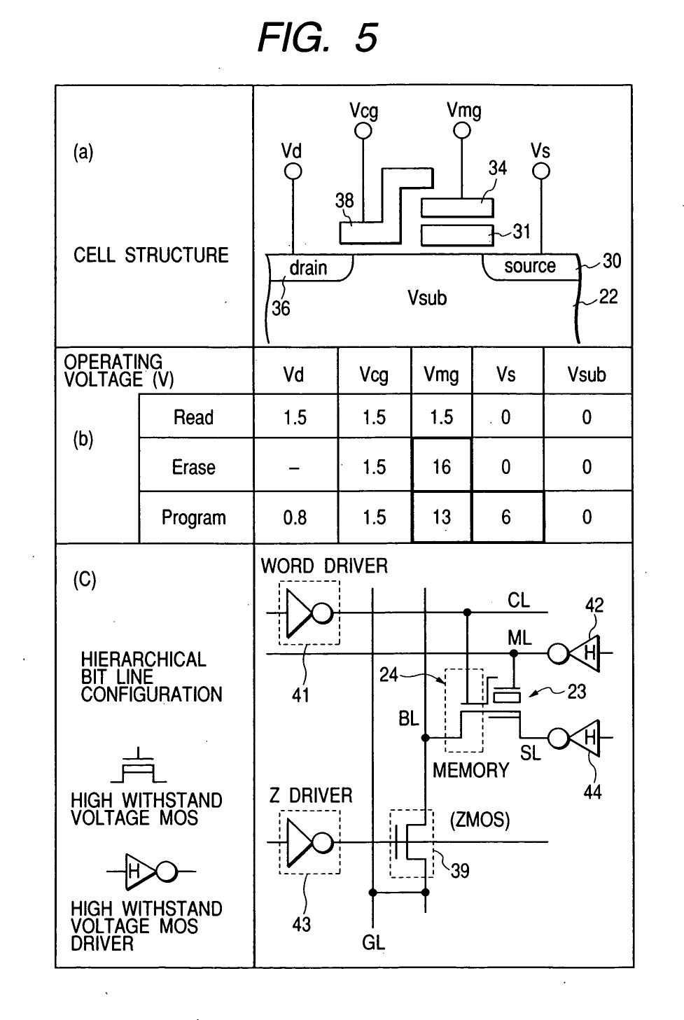

FIG. 5 representatively shows characteristics of the nonvolatile memory cell of FIG. 4. FIG. 5 shows a connection form of the nonvolatile memory cell 21 in a hierarchical bit line structure. The diffusion layer 36 is connected to a sub bit line BL (hereinbelow, also simply written as bit line BL), the diffusion layer 30 is connected to a source line SL, the memory gate electrode 34 is connected to a memory gate control line ML, and the control gate electrode 38 is connected to a control gate control line CL. The sub bit line BL is connected to a main bit line (also written as global bit line) GL via an n-channel type switch MOS transistor (ZMOS) 39. Although not illustrated, a plurality of nonvolatile memory cells 21 are connected to the sub bit line BL, and each of a plurality of bit lines BL is connected to one main bit line GL via the ZMOS 39.

FIG. 5 representatively shows a first driver (word driver) 41 for driving the control gate control line CL, a second driver 42 for driving the memory gate control line ML, a third driver (Z driver) 43 for switch driving the ZMOS 39, and a fourth driver 44 for driving the source line SL. The drivers 42 and 44 take the form of high withstand voltage MOS drivers using MOS transistors having high gate insulating withstand voltage. The drivers 41 and 43 are constructed by drivers using MOS transistors having relatively low gate insulating withstand voltage. For example, each of the drivers 41 and 43 can be constructed by using the same MOS transistor as that in the logic part typified by the CPU 2.

In a writing operation in which a relatively high threshold voltage is set in the first transistor part 23 in the nonvolatile memory cell 21, for example, a memory gate voltage Vmg and a source line voltage Vs are set to high voltages, 1.5V is applied as a control gate voltage Vcg, 0.8V is set for a write selection bit line, and 1.5V is set to a write not-selected bit line. The second transistor part 24 of the write selection bit line is turned on to pass current from the diffusion layer 30 to the diffusion layer 36. It is sufficient to store hot electrons generated around the charge storage region 31 on the control gate electrode 38 side into the charge storage region 31. In the case of writing information by using a write current which is a constant current of a few micro amperes to tens micro amperes, the potential of a write selected bit line is not limited to the ground potential. It is sufficient to apply about 0.8V as described above and to pass the channel current. In the writing operation, for the n-channel type memory cell, the diffusion layer 30 functions as a drain, and the diffusion layer 36 functions as a source. The writing form is injection of hot electrons to the source side.

In an erasing operation in which a relatively low threshold voltage is set in the first transistor part 23, for example, a high voltage is applied as the memory gate voltage Vmg to discharge electrons held in the charge storage region 31 to the memory gate electrode 34. At this time, the ground potential of the circuit is applied to the diffusion layer 30. The second transistor part 24 may be set to an on state.

As obvious from the writing/erasing operation on the first transistor part 23, the invention can be achieved without applying a high voltage to the control gate control line CL and the bit line BL. It guarantees that the gate withstand voltage of the second transistor part 24 may be relatively low. The ZMOS 39 is not requested to have high withstand voltage.

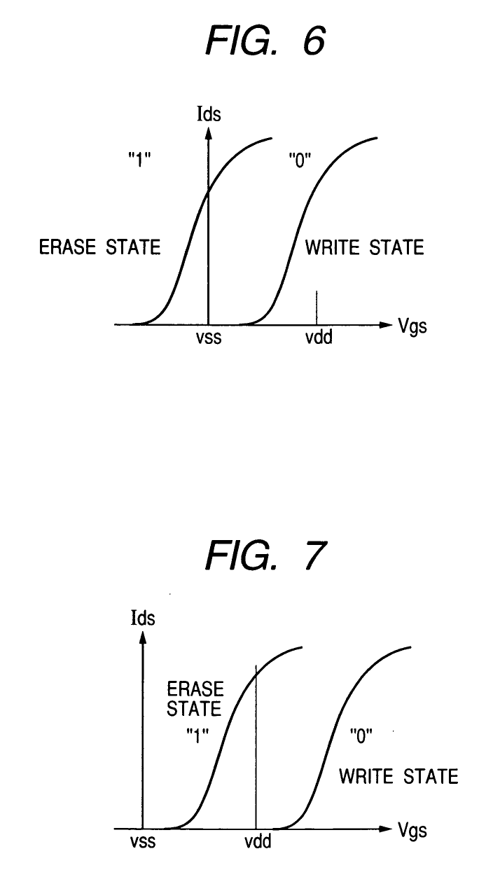

Although not limited, as shown in FIG. 6, the first transistor part 23 in an erase state in which the threshold voltage is set to be low is of the depletion type, and the first transistor part 23 in a write state in which the threshold voltage is set to be high is of an enhancement type. In the erase/write state of FIG. 6, the ground voltage of the circuit may be applied to the memory gate electrode 34 in the reading operation. Further, in the case of increasing the speed of the reading operation, for example, the power source voltage Vdd may be applied to the memory gate electrode 34. On the other hand, in the case of setting the first transistor part 23 in both of the erasing and writing states of the enhancement type as shown in FIG. 7, for example, the power source voltage Vdd is applied to the memory gate electrode 34 in the reading operation.

In the threshold state of FIG. 6, in the operation of reading the nonvolatile memory cell 21 of FIG. 5, the source line voltage Vs is set to 0V, the memory gate voltage Vmg is set to 1.5V, and the control gate voltage Vcg of a memory cell to be selected for reading is set to a selection level of 1.5V. When the second transistor part 24 is turned on, information stored in the bit line BL is read according to whether current flows or not on the basis of the threshold voltage state of the first transistor part 23. The second transistor part 24 has a gate insulation withstand voltage lower than that of the first transistor part 23 and a relatively thin gate oxide film thickness. Consequently, as compared with the case where both the MOS transistor for storing information and the MOS transistor for selection are formed so as to have high withstand voltage, the current supply capability of the whole nonvolatile memory cell 21 can be made relatively high, and the data reading speed can be increased.

Although not shown, in the operation of reading the nonvolatile memory cell 21, the direction of current can be reverse to the forward direction.

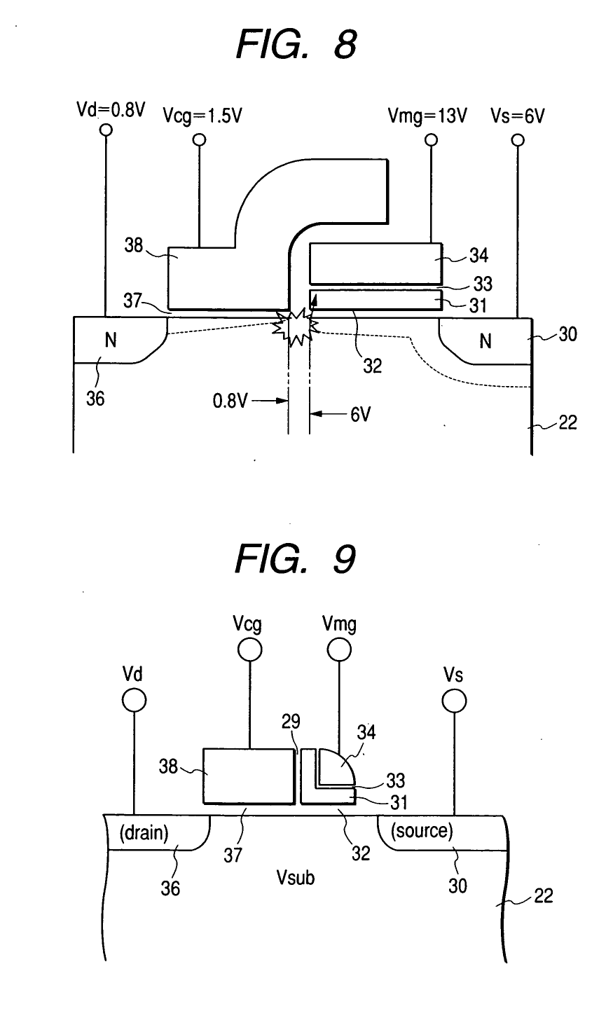

FIG. 8 is a device section when attention is paid to the writing operation of the nonvolatile memory cell of FIG. 5. In a state of the write voltage of the diagram, a channel of 6V is formed close to the control gate electrode 38 directly below the charge storage region 31 while the channel directly below the control gate electrode 38 has 0V. With the arrangement, a sharp electric field is formed directly below the memory gate electrode 38 side of the charge storage region 31, and the current flowing in the channel between the source and the drain can be controlled. By the sharp electric field, hot electrons are generated and stored in the charge storage region 31. Since the channel directly below the control gate electrode 38 has 0V, the thickness of the insulating film 37 of the control gate electrode 38 is assured to be the same or about the same as that of a number of MOS transistors such as a logic circuit requiring no high withstand voltage. In the case of reducing the current, the channel directly below the control gate electrode 38 has about 0.8V.

The reason why the voltage of the channel directly below the control gate electrode 38 does not become 6V in the writing operation is that a high-concentration impurity region such as a diffusion layer is not formed between the bit line electrode 36 and the source line electrode 30 formed in the well region 22. If such a diffusion layer is formed, a source voltage at the time of writing is transmitted to the diffusion layer. Consequently, it becomes necessary to make the gate insulating film in the selection MOS transistor part thick and it becomes difficult to realize high-speed reading.

FIG. 9 shows another sectional structure of the nonvolatile memory cell 1 according to the invention. It is also possible to dispose the charge storage region 31 and the memory gate electrode 34 next to the control gate electrode 38 and use the memory gate electrode 34 as a side wall gate. Although not shown, for the charge storage region 31, it is not limited to employ a charge trapping insulating film covered with an insulating film such as the silicon nitride film but a conductive floating gate electrode (for example, a polysilicon electrode) covered with an insulating film, a conductive particulate layer covered with an insulating film, or the like may be employed. The conductive particulate layer may be constructed by, for example, nano dots of polysilicon.

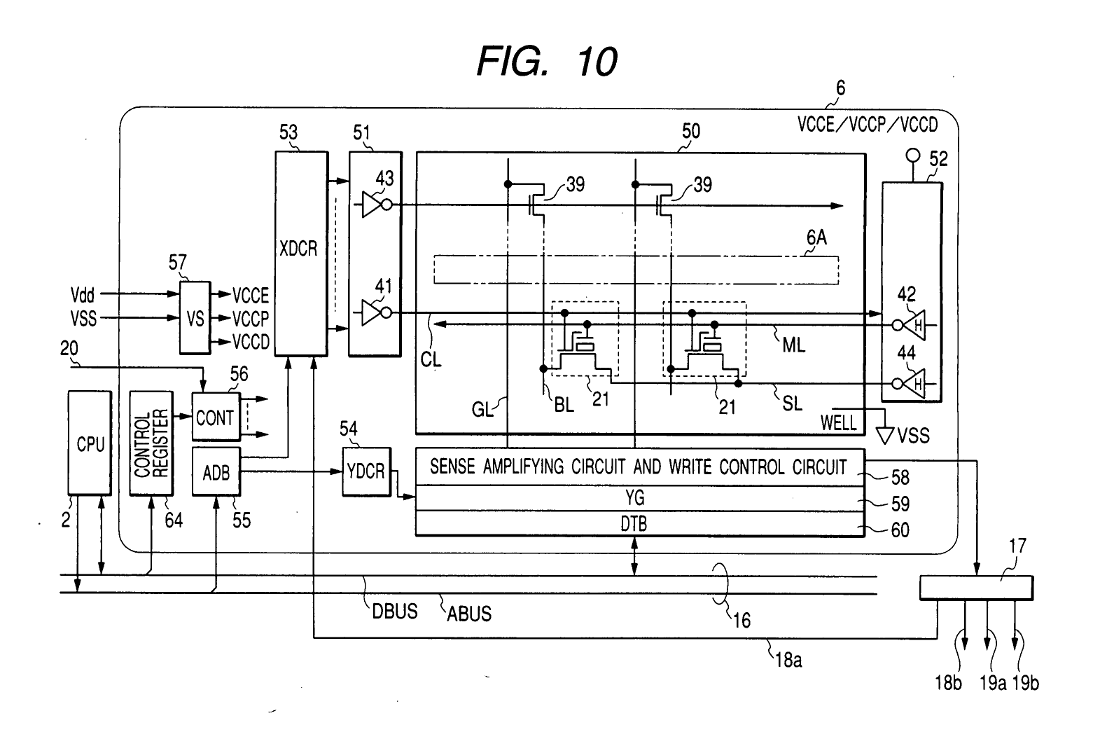

FIG. 10 shows a general configuration of the flash memory 6. A memory array 50 has a hierarchical bit line structure described by referring to FIG. 5 and has the nonvolatile memory cells 21. A driver circuit (DRV) 51 is a circuit block including the drivers 43 and 41 and selects a driver to perform an output operation in accordance with an address decoded signal supplied from an X address decoder (XDCR) 53. A driver circuit (DRV) 52 has the drivers 42 and 44 and selects a driver to perform an output operation in accordance with the state of the control gate control line CL or the like. To the global bit line GL, a sense amplifying circuit and write control circuit 58 is connected. The sense amplifying circuit amplifies data read to the global bit line GL and latches the data. The write control circuit latches write control information to be supplied to the global bit line in the writing operation. The sense amplifying circuit and write control circuit 58 is connected to a data input/output buffer (DTB) 60 via a Y selection circuit (YG) 59 and can interface with the data bus DBUS included in the internal bus 16. In the reading operation, the Y selection circuit (YG) 59 selects read data latched in the sense amplifier circuit in accordance with an address decoded signal output from a Y address decoder (YDCR) 54. The selected read data can be output to the outside via the data input/output buffer 60. In the writing operation, the Y selection circuit 59 selects a global bit line to which write data supplied from the data input/output buffer 60 corresponds and makes the write control circuit latch the write data.

An address signal is supplied from the address bus ABUS to an address buffer 55 and is supplied from the address buffer 55 to the X address decoder 53 and the Y address decoder 54. An operation power necessary for the reading, erasing and writing operations is generated by a voltage generating circuit (VS) 57 on the basis of the external power sources Vdd and Vss. For example, the write operation voltages illustrated in FIG. 5 are assumed as follows; Vdd=1.5V, VCCE=16V, VCCP=13V, and VCCD=6V.

A control circuit (CONT) 56 performs a control sequence of the reading operation, erasing operation, and writing operation of the flash memory 6 and a control of switching the operation power source in accordance with control information that is set in a control register 64. The control of switching the operation power source is a control for properly switching the operation power sources of the drivers 41 to 44 in accordance with the operation mode of FIG. 5 and in accordance with the reading operation, erasing operation, or writing operation.

Repair of Defect by Repair Information

In FIG. 10, to the control circuit 56, the control signal 20 output from the system controller 14 is supplied as a part of the resetting process of the microcomputer 1. The control circuit 56 performs an operation of reading the specific region 6A in the memory array 50 in response to an instruction of the control signal 20 and loads the repair information 18a and 18b and trimming information 19a and 19b to the register 17. The repair information 18a and 18b and trimming information 19a and 19b loaded to the register 17 are latched by registers of the corresponding circuits 6, 5, 13, and 9 synchronously with clock signals. A signal path from the register 17 to a corresponding circuit is, although not limited, constructed by a dedicated signal line. In place of the dedicated signal line, the internal bus 16 may be used.

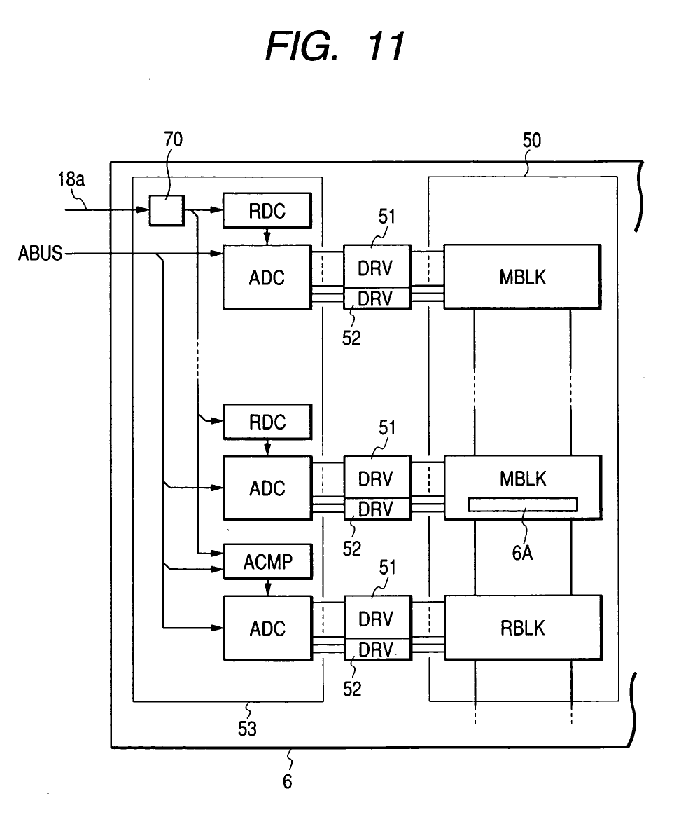

FIG. 11 shows an example of a circuit configuration for redundancy repair in the flash memory 6. The memory array 50 is divided into a plurality of memory blocks MBLK as normal storage regions and has a redundant memory block RBLK as a redundant storage region with which a defective region is replaced on the normal memory block MBLK unit. Each of the normal memory blocks MBLK and the redundant memory block RBLK has the configuration of the memory array shown in FIG. 10. The specific region 6A is assigned to a predetermined normal memory block MBLK. For each of the normal memory blocks MBLK and the redundant memory block RBLK, the driver circuits 51 and 52 are disposed. The decoder 53 has an address decoder ADC and a repair decoder RDC corresponding to each of the normal memory blocks MBLK, and a redundant address decoder RADC and an address comparator ACMP corresponding to the redundant memory block RBLK.

The repair information 18a output from a register 70 is supplied to the repair decoder RDC. The repair information 18a includes repair enable information and repair address information. To the register 70, the repair information 18a is initially loaded from the register 17 in the resetting process of the microcomputer 1. The repair decoder RDEC decodes the repair information and, when repair enable information indicates an enable state, decodes a memory block designated by the repair address information. For example, when the number of normal memory blocks MBLK is 16 and the number of redundant memory block RBLK is 1, the repair decoder RDC decodes repair address information of four bits and, when it is detected that the normal memory block MBLK of itself is designated, makes the address decoder ADC corresponding to itself inactive. The repair address information corresponds to upper bits of an address signal. The address comparator ACMP compares the repair address information with the upper bits of the address signal and, when they coincide with each other, makes the redundant address decoder RADC active. The redundant address decoder RADC has an address decode logic except for the upper bits of the address signal (the number of bits of the repair address information) for the normal address decoder ADC. Therefore, the normal memory block MBLK designated by the repair information can be replaced with the redundant memory block RBLK.

With the configuration, a program for an electric fuse or a laser fuse is not necessary for designation of an object to be repaired. Thus, repair efficiency can be improved with respect to the defect repair.

Although not shown, defect repair for the RAM 5 by repair information can be also similarly performed.

It is sufficient to obtain the repair information in accordance with a result of a device test conducted during a process of manufacturing the microcomputer 1. At the time of initially writing repair information into the specific region 6A, it is sufficient to do it by using an EPROM writer in the second mode. In the case where a redundant configuration which can be used for repair remains when a defect occurs after the microcomputer 1 is mounted on the system, the repair information can be rewritten on board in the first mode.

Adjustment of Characteristics by Trimming Information

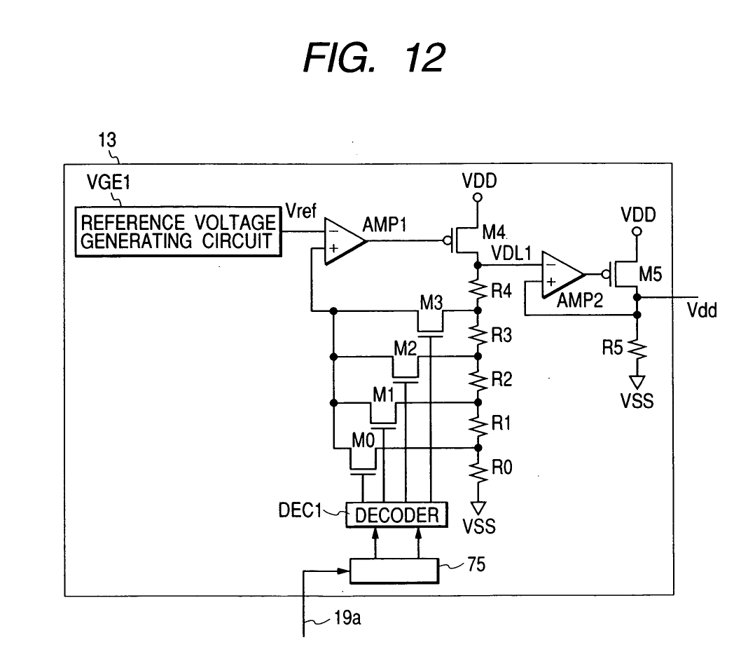

FIG. 12 shows an example of the power source circuit 13. The power source circuit 13 latches the trimming information 19a as control information for determining a reference voltage for specifying the level of the internal power source voltage Vdd in a voltage trimming register 75. The trimming information 19a is initially loaded to the register 75 from the flash memory 6 via the register 17 in response to a resetting instruction in a manner similar to the initial loading of the repair information.

The internal voltage Vdd is output from a source follower circuit constructed by an n-channel type MOS transistor M5 and a resistive element R5. The conductance of the transistor M5 is negative feedback controlled by an operational amplifier AMP2. The voltage Vdd is set to be logically equal to a control voltage VDL1. The control voltage VDL1 is output from a source follower circuit constructed by an n-channel type MOS transistor M4 and resistive elements R0 to R4. The conductance of the transistor M4 is negative feedback controlled by an operational amplifier AMP1. The feedback system constructs a trimming circuit having switch MOS transistors M0 to M3 which can select a resistance voltage dividing ratio by the resistors R0 to R4. Any of the switch MOS transistors M0 to M3 is selected by a decoder DEC1 for decoding the 2-bit voltage trimming information 19a. A feedback voltage generated in such a manner is compared with the reference voltage generated by a reference voltage generating circuit VGE1 by the operational amplifier AMP1. The operational amplifier AMP1 performs a negative feedback control so that the control voltage VDL1 becomes equal to a reference voltage Vref.

When the device characteristics of the power source circuit 13 vary relatively largely due to the influence of the manufacturing process, the resistance voltage dividing ratio selected by the decoder DEC1 is changed so that the internal voltage VDL1 lies within a desired range of design values. The information used for this purpose can be obtained in advance from the circuit characteristics grasped by a device test. As described above, it is sufficient to preliminarily write the information in the specific region 6A in the flash memory 6 in an EPROM writer mode or the like. When the microcomputer 1 is reset, the voltage trimming information 19a is initially loaded from the flash memory 6 to the voltage trimming register 75.

In such a manner, the efficiency of adjusting the circuit characteristics can be improved without requiring a program for an electric fuse or a laser fuse for adjusting the circuit characteristics.

Although not shown, the conversion characteristics adjustment for the A/D converter 9 by the trimming information 19b can be also performed in a manner similar to the above.

Although the invention achieved by the inventors herein has been concretely described on the basis of the embodiments, obviously, the invention is not limited to the embodiments but can be variously changed without departing from the gist.

For example, correspondence between the threshold voltage state and the write/erase state of a nonvolatile memory cell is a relative concept and can be defined opposite to the above. The low threshold voltage state of a nonvolatile memory cell is not necessarily set by the depletion type but may be set by the enhancement type. The operation voltages of writing, erasing, and reading are not limited to those in the description of FIG. 5 but can be properly changed.

The erasing operation is not limited to the form of discharging electrons in the charge storage region 31 to the memory gate 34. The direction of the electric field in the erasing operation may be reversed and electrons in the charge storage region 31 may be discharged to the well region 22.

The bit lines may not employ the hierarchical configuration for the global bit line but may be connected to a sense amplifier circuit or a write circuit.

The thicknesses in the ONO structure of the nonvolatile memory cell may be a combination of 3 nm (nano meters), 26.5 nm, and 0 nm from the channel region side or a combination of 5 nm, 10 nm, and 3 nm.

Peripheral circuits built in the microcomputer are not limited to those in the foregoing embodiment but can be properly changed.

The case of applying the invention achieved by the inventors herein mainly to a microcomputer in the field of utilization as the background of the invention has been described above. The invention is not limited to the case but can be widely applied to various semiconductor data processors such as a system on-chip LSI and the like.

Effects obtained by a representative one of the inventions disclosed in the specification will be briefly described as follows.

A thick high-withstand-voltage MOS transistor which deteriorates high speed can be eliminated from a path of reading information stored in the on-chip nonvolatile memory.

Stored information can be read at high speed from the on-chip nonvolatile memory.

A program for an electric fuse or a laser fuse is unnecessary to designate an object to be repaired, so that the efficiency of repairing a defect can be improved.

A program for an electric fuse or a laser fuse is unnecessary to adjust circuit characteristics, so that the efficiency of adjusting the circuit characteristics can be improved.

Before a data processor is mounted on a system, a program, repair information, and the like can be efficiently written in the nonvolatile memory. Moreover, after the data processor is mounted on the system, the program, repair information, and the like in the nonvolatile memory can be rewritten on board.

What is claimed is:

1. A data processor on a semiconductor substrate comprising:
a plurality of internal circuits including a nonvolatile memory and a central processing unit,
wherein the nonvolatile memory comprises a memory array including electrically erasable and writable nonvolatile memory cells, each of which includes a gate insulating film, a charge storage insulating film for storing information and over the gate insulating film, a memory gate electrode over the charge storage insulating film,
wherein the memory array includes a specific storage region capable of reading data stored in the memory cells therein in response to a reset instruction, and
wherein the data read from said specific storage region is repair information for replacing a normal storage region in a predetermined internal circuit with a redundant storage region in the predetermined internal circuit.

2. A data processor on a semiconductor substrate comprising:
a plurality of internal circuits including a nonvolatile memory and a central processing unit,
wherein the nonvolatile memory comprises a memory array including electrically erasable and writable nonvolatile memory cells, each of which includes a gate insulating film, a charge storage insulating film for storing information and over the gate insulating film, a memory gate electrode over the charge storage insulating film,
wherein the memory array includes a specific storage region capable of reading data stored in the memory cells therein in response to a reset instruction, and
wherein the data read from the specific storage region is trimming information for adjusting characteristics of a predetermined internal circuit.

3. A data processor on a semiconductor substrate comprising:
a plurality of internal circuits including a nonvolatile memory and a central processing unit,
wherein the nonvolatile memory comprises a memory array including electrically erasable and writable nonvolatile memory cells, each of which includes a gate insulating film, a charge storage insulating film for storing information and over the gate insulating film, a memory gate electrode over the charge storage insulating film, and
wherein the data processor comprises an input terminal of an operation mode signal for selectively designating a first mode of allowing a predetermined internal circuit to control rewriting of information stored in said nonvolatile memory or a second mode of allowing an external device connected to the data processor to control the rewriting.

4. The data processor according to claim 1,
wherein the nonvolatile memory cell comprises a first transistor part used for storing information and a second transistor part for selecting the first transistor part,
wherein the first transistor part is of an MONOS type including the charge storage insulating film and a memory gate electrode, and
wherein the second transistor part is of an MOS type.

5. The data processor according to claim 4,
wherein a channel region of the first transistor part and a channel region of the second transistor part are adjacent to each other, and
wherein a gate insulating withstand voltage of the second transistor part is lower than that of the first transistor part.

6. The data processor according to claim 4,
wherein a channel region of the first transistor part and a channel region of the second transistor part are adjacent to each other, and
wherein a gate insulating film of the second transistor part has the same thickness as that of a gate insulating film of an MOS type transistor as a component of the central processing unit.

7. The data processor according to claim 5,
wherein the first transistor part includes a source line electrode connected to a source line, the memory gate electrode connected to a memory gate control line, and the charge storage insulating film disposed directly below the memory gate electrode, and
wherein the second transistor part includes a bit line electrode connected to a bit line and a control gate electrode connected to a control gate control line.

8. The data processor according to claim 7, further comprising:
a switch MOS transistor capable of coupling the bit line to a global bit line,
wherein a gate oxide film of the switch MOS transistor is thinner than that of the first transistor part.

9. The data processor according to claim 8, comprising:
a first driver for driving the control gate control line;
a second driver for driving the memory gate control line;
a third driver for driving the switch MOS transistor to an on state; and
a fourth driver for driving the source line,
wherein the first and third drivers use a first voltage as an operation power source, and the second and fourth drivers use a voltage higher than the first voltage as an operation power source.

10. The data processor according to claim 9, further comprising:
a control circuit, at the time of increasing a threshold voltage of said first transistor part, for setting the operation power source of the first driver as a first voltage, setting the operation power source of the fourth driver as a second voltage higher than the first voltage, setting the operation power source of the second driver as a third voltage higher than the second voltage, and enabling hot electrons to be injected from a bit line electrode side into a charge storage region.

11. The data processor according to claim 10, wherein at the time of decreasing the threshold voltage of the first transistor part, the control circuit sets the operation power source of the second driver as a fourth voltage higher than the third voltage, and discharges electrons from the charge storage region to the memory gate electrode.

12. The data processor according to claim 11, wherein the first transistor part whose threshold voltage is set to be low is of a depletion type, and the first transistor part whose threshold voltage is set to be high is of an enhancement type.

13. A data processor on a semiconductor substrate comprising:
a plurality of internal circuits including a nonvolatile memory and a central processing unit, and
an input terminal of an operation mode signal for selectively designating a first mode of allowing a first internal circuit to control rewriting of information stored in the nonvolatile memory or a second operation mode of allowing an external device coupled to the data processor to control the rewriting,
wherein the nonvolatile memory comprises a memory array including electrically erasable and writable nonvolatile memory cells, each of which includes a gate insulating film, a charge storage insulating film for storing information and over the gate insulating film, a memory gate electrode over the charge storage insulating film,
wherein the memory array includes a specific storage region capable of reading data stored in the memory cells therein in response to a reset instruction, and
wherein the data read from said specific storage region includes:
repair information for replacing a normal storage region in a second internal circuit with a redundant storage region in the second internal circuit, and
trimming information for adjusting characteristics of a third internal circuit.
